(19) United States
(12) Patent Application Publication
(10) Pub. No.: US 2020/0411776 A1
(43) Pub. Date: Dec. 31, 2020

(54) ORGANIC LIGHT EMITTING DIODE DISPLAY PANEL AND METHOD OF MANUFACTURING THEREOF

(71) Applicant: WHUAN CHINA STAR OPTOELECTRONICS SEMICONDUCTOR DISPLAY TECHNOLOGY CO.,LTD, Wuhan,Hubei (CN)

(72) Inventors: Shiyan XIAO, Wuhann, Hubei (CN); Jiuhong PENG, Wuhan, Hubei (CN)

(21) Appl. No.: 16/630,450

(22) PCT Filed: Oct. 21, 2019
(86) PCT No.: PCT/CN2019/112166

§ 371 Date: Jan. 12, 2020

(30) Foreign Application Priority Data
Jun. 25, 2019 (CN) 201910552660.3

(51) Int. Cl. H01L 51/00; H01L 27/32; H01L 51/52; H01L 51/56

(52) U.S. Cl. CPC H01L 51/0096; H01L 27/3234; H01L 2227/323; H01L 51/5253; H01L 51/56; H01L 27/3244

(57) ABSTRACT

An organic light emitting diode display panel and a method of manufacturing thereof. The organic light emitting diode display panel includes a substrate, a driving circuit layer, an organic light emitting diode layer, and a thin film encapsulation layer, which are disposed in order. The thin film encapsulation layer extends through the third through hole disposed on the organic light emitting diode layer and covers the organic light emitting diode layer.

### BACKGROUND OF INVENTION

### Field of Invention

The present invention relates to the field of display, and more particularly, to an organic light emitting diode display panel and a method of manufacturing thereof.

### Description of Prior Art

Currently, mobile electronic devices such as mobile phones have been widely used in people's daily work and life, and become a necessity for people to carry around. Moreover, in order to satisfy people's social and entertainment, mobile electronic devices generally have a camera function. Cameras are widely used in display screens and tablets, but most traditional cameras are directly exposed, and an area dedicated to the installation of the camera is reserved on the front or back of the mobile electronic device, and the camera needs to be exposed to be able to capture image information of the external object through a photosensitive element in the camera.

With the development of display technology, camera under panel (CUP) technology has been widely recognized, but current application of the screen camera is implemented by liquid crystal display (LCD) technology.

For an organic light emitting display (OLED) display device, it is necessary to form an opening in the display panel of the display device to ensure that a functional device such as a camera can be disposed in the opening area of the display panel of the display device. However, when forming an opening for the under-screen camera, a laser is generally used to perform the opening operation on the side of the thin film encapsulation layer after completing the display panel and the thin film encapsulation layer.

Since the organic material of the light emitting layer of the organic light emitting diode display device is relatively sensitive to external moisture, the thin film encapsulation layer needs to be formed on the device to block the external moisture, which erodes the light emitting material. But the light emitting layer formed at the opening is not encapsulated by the thin film encapsulation layer. Meanwhile, the thin film encapsulation layer does not protect the light emitting layer.

The thin film encapsulation layer is made of an inorganic material. When an opening is formed on the thin film encapsulation layer of the display panel by laser, a risk of cracking in the thin film encapsulation layer may be caused. Thus, integrity of the thin film encapsulating layer is damaged, which seriously affects the encapsulating performance of the device and greatly reduces the service life of the device.

### SUMMARY OF INVENTION

In order to solve the above-mentioned problems, an organic light emitting diode display panel is provided, and the organic light emitting diode display panel includes:

a substrate having a first through hole;

a driving circuit layer disposed on the substrate, and the driving circuit layer is provided with a second through hole corresponding to the first through hole of the substrate, and the second through hole has a diameter equal to a diameter of the first through hole;

an organic light emitting diode layer disposed on the driving circuit layer, wherein the organic light emitting diode layer is provided with a third through hole corresponding to the first through hole and the second through hole, and a diameter of the third through hole is greater than a diameter of the second through hole; and

a thin film encapsulation layer disposed on the organic light emitting diode layer, and the thin film encapsulation layer covers the organic light emitting diode layer.

In one embodiment, the thin film encapsulation layer extends through the third through hole and further extends onto the driving circuit layer, and the thin film encapsulation layer completely covers the organic light emitting diode layer.

In one embodiment, the thin film encapsulation layer includes a fourth through hole corresponding to the first through hole, and a diameter of the fourth through hole is equal to a diameter of the first through hole.

In one embodiment, the organic light emitting diode layer includes:

a buffer layer;

a hole injection transport layer disposed on the buffer layer;

a functional layer disposed on the hole injection transport layer;

a light emitting layer disposed on the functional layer;

a doped electron transport layer disposed on the light emitting layer;

a cathode layer disposed on the doped electron transport layer; and

a cover layer disposed on the cathode layer.

A method of manufacturing an organic light emitting diode display panel includes following steps:

providing a substrate;

forming a driving circuit layer on the substrate;

attaching a shielding sheet to the driving circuit layer;

forming an organic light emitting diode layer on the driving circuit layer, and the organic light emitting diode layer is provided with a third through hole corresponding to the shielding sheet, and a diameter of the third through hole is equal to a diameter of the shielding sheet;

forming a second through hole on the driving circuit layer by a laser cutting at a position corresponding to the shielding sheet;

forming a first through hole on the substrate and removing the shielding sheet, and a diameter of the second through hole is equal to a diameter of the first through hole, and a diameter of the first through hole is less than a diameter of the shielding sheet; and

forming a thin film encapsulation layer on the organic light emitting diode layer, and the thin film encapsulation layer covers the organic light emitting diode layer.

In one embodiment, the shielding sheet has a coefficient of thermal expansion of 1.4×10⁻⁶/° C. to 1.8×10⁻⁶ 1° C. at 20° C.

In one embodiment, the shielding sheet has a thermal conductivity of 0.026 cal/cm·sec·° C. to 0.032 cal/cm·sec·° C.

In one embodiment, material of the shielding sheet comprises invar, and a thickness of the shielding sheet is 50 μm to 100 μm.

In one embodiment, a step of the attaching the shielding sheet close to the substrate is achieved by an inorganic high temperature resistant adhesive agent.

In one embodiment, the step of forming an organic light emitting diode layer on the driving circuit layer includes the following steps:

forming a buffer layer on the driving circuit layer;

forming a hole injection transport layer on the buffer layer;

forming a functional layer on the hole injection transport layer;

forming a light emitting layer on the functional layer;

forming a doped electron transport layer on the light emitting layer;

forming a cathode layer on the doped electron transport layer; and

forming a cover layer on the cathode layer.

An advantageous effect of the present invention is described as follows. An organic light emitting diode display panel and a method of manufacturing thereof. Using the shielding sheet to block the circuit driving layer, forming the organic light emitting diode layer, using the laser to cut the opening, and then encapsulating, so that it ensures that the thin film encapsulating layer covers the organic light emitting diode layer, and the organic light emitting diode layer is protected. The entire emitting area and the effectiveness of the encapsulation area are achieved, thereby increasing the service life of the OLED display panel. Moreover, the method does not require to carry vapor deposition for two times to form a film, which greatly improves the productivity and material utilization rate; no need to add a mask, which greatly reduces the difficulty of designing and manufacturing, thereby effectively saving cost; it is merely necessary to increase the alignment bonding machine and the laser cutting machine before and after the vapor deposition process, thereby achieving mass production quickly.

### BRIEF DESCRIPTION OF DRAWINGS

FIG. 1 is a schematic view of an organic light emitting diode display panel according to one embodiment of the present invention.

FIG. 2 is a schematic view of the organic light emitting diode layer according to one embodiment of the present invention.

FIG. 3 is a flowchart of a method of manufacturing an organic light emitting diode display panel according to one embodiment of the present invention.

FIG. 4 is a schematic view of the step of manufacturing the organic light emitting diode layer in FIG. 3.

FIG. 5 is a top plan view of the shielding sheet completely removed by laser cutting in FIG. 3.

FIG. 6 is a flowchart of a method of manufacturing the organic light emitting diode layer according to one embodiment of the present invention.

### REFERENCE NUMERALS

substrate 1; drive circuit layer 2; organic light emitting diode layer 3; thin film encapsulation layer 4; shielding sheet 10; first through hole 11; second through hole 12; third through hole 13; fourth through hole 14; inorganic high temperature resistant adhesive 20; buffer layer 31; hole injection transport layer 32; functional layer 33; light emitting layer 34; doped electron transport layer 35; cathode layer 36; cover layer 37; and organic light emitting diode display panel 100.

### DETAILED DESCRIPTION OF PREFERRED EMBODIMENTS

Directional terms mentioned in this application, such as “up,” “down,” “forward,” “backward,” “left,” “right,” “inside,” “outside,” “side,” etc., are merely indicated the direction of the drawings. Therefore, the directional terms are used for illustrating and understanding of the application rather than limiting thereof. In the drawings, similar structures are marked with identical reference numerals.

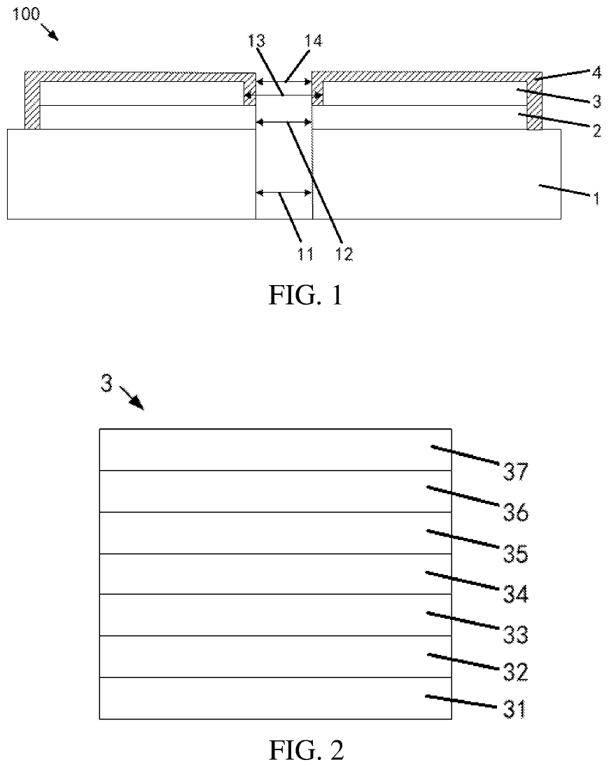

Referring to FIG. 1, in the first embodiment of the present invention, an organic light emitting diode display panel 100 includes a substrate 1, a driving circuit layer 2, an organic light emitting diode layer 3, and a thin film encapsulation layer 4, which are disposed in order. A through hole for mounting the camera is disposed at a position corresponding to the camera. Specifically, the through hole includes a first through hole 11, a second through hole 12, a third through hole 13, and a fourth through hole 14 surrounding the third through hole 13. All of the first through hole 11, the second through hole 12, and the fourth through hole 14 have the same diameter, and through holes corresponds to an opening of the camera position. The diameter of the third through hole 13 is greater than the diameter of the fourth through hole 14, so that the thin film encapsulation layer 4 covers the organic light emitting diode layer 3.

Specifically, the first through hole 11 is disposed on the substrate 1. The driving circuit layer 2 is disposed on the substrate 1. The driving circuit layer 2 is provided with a second through hole 12 corresponding to the first through hole 11 of the substrate 1, and the second through hole 12 has a diameter equal to a diameter of the first through hole 11. The organic light emitting diode layer 3 is disposed on the driving circuit layer 2. The organic light emitting diode layer 3 is provided with a third through hole 13 corresponding to the first through hole 11 and the second through hole 12, and a diameter of the third through hole 13 is greater than a diameter of the second through hole 12. The thin film encapsulation layer 4 is disposed on the organic light emitting diode layer 3. The thin film encapsulation layer 4 covers the organic light emitting diode layer 3, so the organic light emitting diode layer 3 is protected. The thin film encapsulation layer 4 includes a fourth through hole 14 corresponding to the first through hole 11, and the diameter of the fourth through hole 14 is equal to the diameter of the first through hole 11.

The diameter of the third through hole 13 is greater than the diameter of the second through hole 12 by 80 μm to 120 μm, and preferably the diameter of the third through hole 13 is greater than the diameter of the second through hole 12 by 100 μm. The driving circuit layer 2 includes a thin film transistor so to provide circuit for the entire organic light emitting diode display panel 100. The thin film encapsulation layer 4 blocks moisture and improves the performance of the organic light emitting diode display panel 100.

In the embodiment, the thin film encapsulation layer 4 extends through the third through hole 13 and further extends onto the driving circuit layer 2, and the thin film encapsulation layer 4 completely covers the organic light emitting diode layer 3.

The thin film encapsulation layer 4 is disposed around the third through hole 13, so the fourth through hole 14 is formed. That is, the third through hole 13 and the fourth through hole 14 are formed at the same position.

Referring to FIG. 2, the organic light emitting diode layer 3 includes a buffer layer 31, a hole injection transport layer 32, a functional layer 33, a light emitting layer 34, a doped electron transport layer 35, a cathode layer 36, and a cover layer 37. Specifically, the hole injection transport layer 32 is disposed on the buffer layer 31. The functional layer 33 is disposed on the hole injection transport layer 32. The light emitting layer 34 is disposed on the functional layer 33. The doped electron transport layer 35 is disposed on the light emitting layer 34. The cathode layer 36 is disposed on the doped electron transport layer 35. The cover layer 37 is disposed on the cathode layer 36.

The material of the buffer layer 31 is polyimide (PI) or other buffer material, which serves as a buffer protection. The light emitting layer 34 obtains an electrical signal for emitting. The cover layer 37 completely covers the upper surface of the cathode layer 36 so as to protect the thin film transistor layer, and the cover layer 37 blocks moisture so as to improve the performance of the display panel.

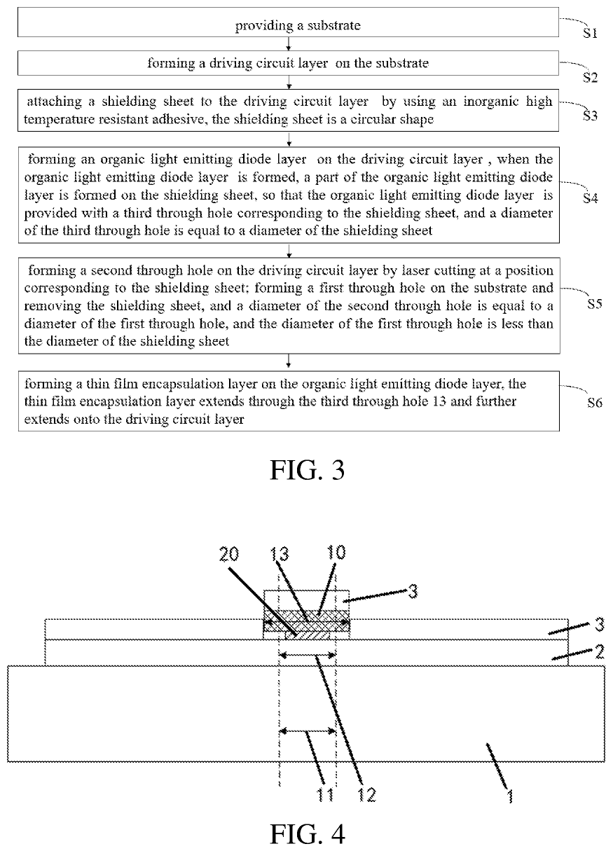

Referring to FIG. 3, a method of manufacturing an organic light emitting diode display panel 100 provided according to one embodiment of the present invention includes the following steps:

S1, providing a substrate 1;

S2, forming a driving circuit layer 2 on the substrate 1;

S3, attaching a shielding sheet to the driving circuit layer 2 by using an inorganic high temperature resistant adhesive 20, the shielding sheet 10 is a circular shape;

S4, forming an organic light emitting diode layer 3 on the driving circuit layer 2, when the organic light emitting diode layer 3 is formed, a part of the organic light emitting diode layer 3 is formed on the shielding sheet 10, so that the organic light emitting diode layer 3 is provided with a third through hole 13 corresponding to the shielding sheet 10, and a diameter of the third through hole 13 is equal to a diameter of the shielding sheet 10. FIG. 4 is a schematic view of steps of manufacturing the organic light emitting diode layer 3;

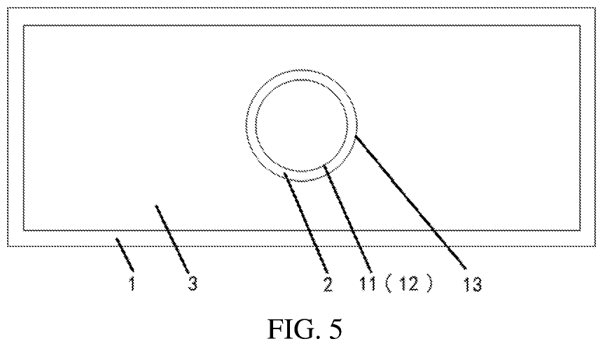

S5, forming a second through hole 12 on the driving circuit layer 2 by laser cutting at a position corresponding to the shielding sheet 10 (see dotted line in FIG. 4), and forming a first through hole 11 on the substrate 1 and removing the shielding sheet 10; since attaching a shielding sheet to the driving circuit layer 2 by using an inorganic high temperature resistant adhesive 20, the diameter of the inorganic high temperature resistant adhesive 20 is less than the diameter of the second through hole 12 or the diameter of the first through hole 11, so to facilitate cutting the shielding sheet 10 by laser and separate the shielding sheet 10; it is convenient to completely remove the shielding sheet 10 and a part of the organic light emitting diode layer 3 formed on a side of the shielding sheet 10 facing away from the driving circuit layer 2; a diameter of the second through hole 12 is equal to a diameter of the first through hole 11, and a diameter of the first through hole 11 is less than a diameter of the shielding sheet 10; that is, the diameter of the third through hole 13 is less than the diameter of the shielding sheet 10; FIG. 5 is a top plan view of the shielding sheet 10 completely removed by laser cutting, and the driving circuit layer 2 is exposed at a position corresponding to the third through hole 13; and

S6, forming a thin film encapsulation layer 4 on the organic light emitting diode layer 3, the thin film encapsulation layer 4 extends through the third through hole 13 and further extends onto the driving circuit layer 2, and the thin film encapsulation layer covers the organic light emitting diode layer 3 and protects the same. FIG. 1 shows the organic light emitting diode display panel structure.

According to the method of manufacturing the display panel, the third through hole 13 is formed by using the shielding sheet 10 to block the organic light emitting diode layer 3, and then the driving circuit layer 2 and the substrate 1 are further cut by laser to form a second through hole 12 on the driving circuit layer 2 and a first through hole 11 on the substrate 1. The diameter of the second through hole 12 is equal to the diameter of the first through hole 11 and both are less than the diameter of the third through hole 13, and thus when the thin film encapsulation layer 4 is formed, the thin film encapsulation layer 4 can completely cover the organic light emitting diode layer 3 and the driving circuit layer 2 so as to enhance the moisture blocking performance of the display panel, improves the encapsulation effect of the thin film encapsulation layer, and extends the service life of the display panel. The thin film encapsulation layer 4 forms a fourth through hole 14 at a position corresponding to the first through hole 11, the diameter of the fourth through hole 14 is equal to the diameter of the first through hole 11. That is, the first through hole 11 and the fourth through hole 14 constitute an opening, which is capable of ensuring entire emitting area and encapsulation area, so the camera is mounted. Therefore, camera under panel (CUP) technology of the organic light emitting diode (OLED) display panel 100 is achieved.

In one embodiment, the shielding sheet 10 has a coefficient of thermal expansion of 1.4×10⁻⁶/° C. to 1.8×10⁻⁶/° C. at 20° C., preferably 1.6×10⁻⁶/□. The range of thermal expansion coefficient ensures that the shielding sheet can be used in a high temperature and a high vacuum environment (80° C. to 100° C., less than 5E-4 Pa).

In one embodiment, the thermal conductivity of the shielding sheet 10 is 0.026 cal/cm·sec·° C. to 0.032 cal/cm·sec·° C. The range of thermal conductivity ensures that the shielding sheet can be used in a high temperature and a high vacuum environment (80° C. to 100° C., less than 5E-4 Pa).

In one embodiment, the material of the shielding sheet 10 includes Invar. Invar is a kind of iron-nickel alloy. A thickness of the shielding sheet 10 ranges from 50 μm to 100 μm.

In one embodiment, the attaching a shielding sheet 10 close to the substrate 1 is achieved by an inorganic high temperature resistant adhesive agent 20. The inorganic high temperature resistant adhesive agent 20 is preferably XZ-T002 model to ensure that it can be used in a high temperature and a high vacuum environment (80° C. to 100° C., less than 5E-4 Pa).

In addition, the fitting accuracy of the shielding sheet 10 is achieved by Mark alignment.

Referring to FIG. 5, the shielding sheet 10, the first through hole 11, the second through hole 12, the third through hole 13, and the fourth through hole 14 are circular shapes. The path of laser cutting is also circular. The shapes of the first through hole 11 and the second through hole 12 are determined by a path of laser cutting, and the shapes of the third through hole 13 and the fourth through hole 14 are determined by the shape of the shielding sheet 10.

It should be noted that, in other embodiments, the shielding sheet 10, the first through hole 11, the second through hole 12, the third through hole 13, and the fourth through hole 14 may be a rectangle shape, a triangle shape, a polygon shape, etc. based on actual needed at the same time, and it is merely to set the shape of the shielding sheet 10 corresponding to the shape of the laser cutting path, and the setting is good for variation.

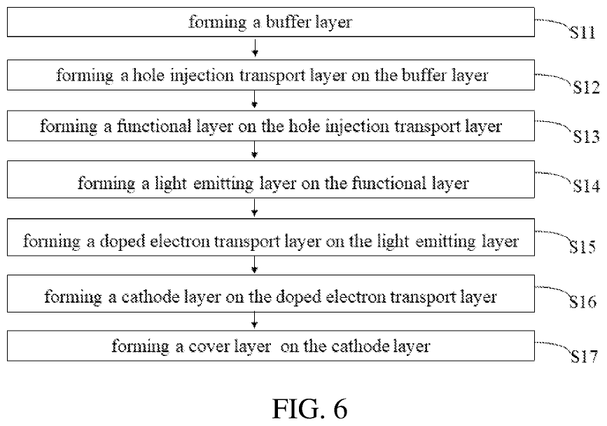

Referring to FIG. 6, the step S6 of forming an organic light emitting diode layer 3 on the driving circuit layer 2 includes the following steps:

S11, forming a buffer layer 31;

S12, forming a hole injection transport layer 32 on the buffer layer 31;

S13, forming a functional layer 33 on the hole injection transport layer 32;

S14, forming a light emitting layer 34 on the functional layer 33;

S15, forming a doped electron transport layer 35 on the light emitting layer 34;

S16, forming a cathode layer 36 on the doped electron transport layer 35; and

S17, forming a cover layer 37 on the cathode layer 36.

An advantageous effect of the present invention is described as follows. An organic light emitting diode display panel and a method of manufacturing thereof. Using the shielding sheet to block the circuit driving layer, forming the organic light emitting diode layer, using the laser to cut the opening, and then encapsulating, so that it ensures that the thin film encapsulating layer covers the organic light emitting diode layer, and the organic light emitting diode layer is protected. The entire emitting area and the effectiveness of the encapsulation area are achieved, thereby increasing the service life of the OLED display panel. Moreover, the method does not require to carry vapor deposition for two times to form a film, which greatly improves the productivity and material utilization rate; no need to add a mask, which greatly reduces the difficulty of designing and manufacturing, thereby effectively saving cost; it is merely necessary to increase the alignment bonding machine and the laser cutting machine before and after the vapor deposition process, thereby achieving mass production quickly.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. An organic light emitting diode display panel, comprising:
a substrate having a first through hole;
a driving circuit layer disposed on the substrate, wherein the driving circuit layer is provided with a second through hole corresponding to the first through hole of the substrate, and the second through hole has a diameter equal to a diameter of the first through hole;
an organic light emitting diode layer disposed on the driving circuit layer, wherein the organic light emitting diode layer is provided with a third through hole corresponding to the first through hole and the second through hole, and a diameter of the third through hole is greater than a diameter of the second through hole; and
a thin film encapsulation layer disposed on the organic light emitting diode layer, wherein the thin film encapsulation layer covers the organic light emitting diode layer.

2. The organic light emitting diode display panel according to claim 1, wherein the thin film encapsulation layer extends through the third through hole and further extends onto the driving circuit layer, and the thin film encapsulation layer completely covers the organic light emitting diode layer.

3. The organic light emitting diode display panel according to claim 1, wherein the thin film encapsulation layer comprises a fourth through hole corresponding to the first through hole, and a diameter of the fourth through hole is equal to a diameter of the first through hole.

4. The organic light emitting diode display panel according to claim 1, wherein the organic light emitting diode layer comprises:
a buffer layer;
a hole injection transport layer disposed on the buffer layer;
a functional layer disposed on the hole injection transport layer;
a light emitting layer disposed on the functional layer;
a doped electron transport layer disposed on the light emitting layer;
a cathode layer disposed on the doped electron transport layer; and
a cover layer disposed on the cathode layer.

5. A method of manufacturing an organic light emitting diode display panel, comprising following steps:
providing a substrate;
forming a driving circuit layer on the substrate;
attaching a shielding sheet to the driving circuit layer;
forming an organic light emitting diode layer on the driving circuit layer, wherein the organic light emitting diode layer is provided with a third through hole corresponding to the shielding sheet, and a diameter of the third through hole is equal to a diameter of the shielding sheet;
forming a second through hole on the driving circuit layer by laser cutting at a position corresponding to the shielding sheet;
forming a first through hole on the substrate and removing the shielding sheet, wherein a diameter of the second through hole is equal to a diameter of the first through hole, and the diameter of the first through hole is less than the diameter of the shielding sheet; and
forming a thin film encapsulation layer on the organic light emitting diode layer, wherein the thin film encapsulation layer covers the organic light emitting diode layer.

6. The method of manufacturing the organic light emitting diode display panel according to claim 5, wherein the shielding sheet has a coefficient of thermal expansion of 1.4×10⁻⁶/° C. to 1.8×10⁻⁶ 1° C. at 20° C.

7. The method of manufacturing the organic light emitting diode display panel according to claim 5, wherein the shielding sheet has a thermal conductivity of 0.026 cal/cm·sec·° C. to 0.032 cal/cm·sec·° C.

8. The method of manufacturing the organic light emitting diode display panel according to claim 5, wherein material of the shielding sheet comprises invar, and a thickness of the shielding sheet is 50 μm to 100 μm.

9. The method of manufacturing the organic light emitting diode display panel according to claim 5, wherein a step of the attaching the shielding sheet close to the substrate is achieved by an inorganic high temperature resistant adhesive agent.

10. The method of manufacturing the organic light emitting diode display panel according to claim 5, wherein the step of forming an organic light emitting diode layer on the driving circuit layer comprises the following steps:
forming a buffer layer on the driving circuit layer;
forming a hole injection transport layer on the buffer layer;
forming a functional layer on the hole injection transport layer;
forming a light emitting layer on the functional layer;
forming a doped electron transport layer on the light emitting layer;
forming a cathode layer on the doped electron transport layer; and
forming a cover layer on the cathode layer.
